(19) United States
(12) Patent Application Publication
(10) Pub. No.: US 2026/0242207 A1
(43) Pub. Date: Aug. 20, 2026

(54) MICROFLUIDIC CONVEYING SYSTEM AND METHOD FOR OPERATING A MICROFLUIDIC CONVEYING SYSTEM

(71) Applicant: Robert Bosch GmbH, Stuttgart (DE)

(72) Inventors: Florian Fetzer, Kirchentellinsfurt (DE); Jochen Reinmuth, Reutlingen (DE)

(21) Appl. No.: 19/530,791

(22) Filed: Feb. 5, 2026

(30) Foreign Application Priority Data
Feb. 17, 2025 (DE) 10 2025 105 774.5

(51) Int. Cl. B81B 3/00; H04R 1/42

(52) U.S. Cl. CPC B81B 3/0059; H04R 1/42; B81B 2201/033; B81B 2201/036; B81B 2203/0127; B81B 2203/0136; B81B 2203/0315; B81B 2203/04; B81B 2203/051; H04R 2201/003

(57) ABSTRACT

A microfluidic conveying system. The microfluidic system includes: a substrate; a chamber formed in the substrate; a ceiling region and a floor region that bound the chamber; and first and second openings that allow a flow of medium through the chamber. The chamber is assigned at least one component that generates a pressure difference. The pressure difference is modulated by valve structures to form a directed flow of medium. The use of the microfluidic conveying system in MEMS-based loudspeakers, in particular in micro-loudspeakers, is also described.

### CROSS REFERENCE

The present application claims the benefit under 35 U.S.C. § 119 of Germany Patent Application No. DE 10 2025 105 774.5 filed on Feb. 17, 2025, which is expressly incorporated herein by reference in its entirety.

### FIELD

The present disclosure relates to a microfluidic conveying system with a substrate and a chamber formed in the substrate, wherein the chamber is bounded by a ceiling region and a floor region, and wherein first and second openings allow an exchange of medium through the chamber. Furthermore, the present disclosure relates to a method for operating a microfluidic conveying system and to the use of the microfluidic conveying system.

### BACKGROUND INFORMATION

Germany Patent Application No. DE 10 2017 203 722 A1 describes a microelectromechanical component (MEMS) with a movable element comprising three electrodes, wherein the movable element is configured to perform a movement according to electrical potentials between the electrodes. The electrodes can be connected to a substrate via spring elements. The MEMS can be part of a MEMS transducer, such as a loudspeaker, a pump, or a valve. A substrate is disclosed which comprises a plurality of layers and a MEMS structure placed in the middle layer, wherein the MEMS layer is surrounded by a fluid. The movement of the movable element in the MEMS, which is achieved by controlling the electrodes, can cause a movement of the surrounding fluid. By installing a passive valve that reduces or also prevents fluid flow in one direction, the MEMS transducer can also be used as a MEMS pump.

Germany Patent Application No. DE 10 2017 206 766 A1 relates to a MEMS transducer that can be used as a MEMS pump, wherein the MEMS transducer has two deformable elements with a beam structure, that are clamped on both sides of a substrate. Alternatively, MEMS transducers with only one deformable element or more than two deformable elements have also been disclosed. The deformable elements can be located adjacent to valve structures, wherein the valve structures are designed to reduce or prevent the flow of the volumetric flow through the opening, at least along one direction. The valve structures can be designed passively as a check valve or actively, which means that they can also be directly controlled. The MEMS transducer can be designed such that the deformable elements are formed as capacitor plates which move toward each other due to an electrical potential difference until an element acting as a bending spring exerts a corresponding mechanical counterforce.

Europe Patent Application NO. EP 3 474 572 A1 describes a MEMS device with a front support element, a rear support element and a folded membrane which is attached to the support elements in such a way that it is connected to a front mold plate and a rear mold plate and thus forms two chambers. The membrane is arranged in proximity to a plurality of valves. The membrane comprises a plurality of membrane units, wherein, in one embodiment, piezoelectric electrodes are each attached on one side of the membrane units in such a way that these units can deform horizontally in one direction. The horizontal deformation of the membrane units increases or decreases the pressure in the two chambers.

MEMS-based speakers (μ-speakers) have great market potential due to higher sound quality and potentially lower energy consumption. However, many designs have problems when it comes to achieving sufficiently high sound power. One factor is the fact that increased sound power requires an increased displaced volume. This increased volume can be achieved, for example, by a greater deflection of a membrane and by larger chip dimensions. However, both of these are to be avoided from an economic point of view, as chip size, for example, is a relevant factor in determining product costs. Various designs have been devised to enable high sound power with a small chip size. One possible solution for sufficiently high SPLs (sound pressure level), in particular in the lower frequency range, are ultrasonically modulated designs such as those disclosed in US 2022/224999 A1. Such designs are based on a pump-like structure and one or more valve devices to modulate a target frequency by selectively increasing and decreasing pressure.

However, existing designs primarily use vibrating membrane structures as valves, which close or open depending on their phase relative to each other. These exhibit a relatively high power loss, which reduces pumping efficiency. This in turn has a direct influence on the achievable sound power of the component.

### SUMMARY

According to the present disclosure, a microfluidic conveying system is provided. According to an example embodiment, the microfluidic conveying system comprises:
a substrate,
a chamber formed in the substrate,
a ceiling region and a floor region that bound the chamber,
first and second openings that allow an exchange of medium through the chamber, wherein at least one component generating a pressure difference is assigned to the chamber, and the pressure difference is modulated by controlled valve structures to form a directed flow of medium.

The solution provided according to the present disclosure makes it possible to open and close the openings alternately, thus enabling a flow of medium into and out of the chamber. Advantageously, the solution proposed according to the present disclosure allows a directed pump current to be generated in one direction or the other when switched correctly.

Advantageously, the at least one component generating a pressure difference is designed as a planar or comb-like electrode structure, and the valve structures 1 and 2 each comprise at least one movable valve part.

Furthermore, the microfluidic conveying system provided according to the present disclosure is characterized in that, in each case, the at least one movable valve part interacts with at least one corresponding stationary part received in the chamber.

In an advantageous further development of the microfluidic conveying system, the at least one stationary valve part is formed in the chamber on projections of a frame structure surrounding the chamber.

In the microfluidic conveying system according to the present disclosure, it is further provided that the valve structures 1 and 2 each have a movable valve part as well as a stationary valve part, or have individual lamella parts which are arranged in a comb structure and can be positioned in or out of overlap with each other, for opening or closing the first and second openings.

Advantageously, in the microfluidic conveying system according to the present disclosure, the at least one movable valve part is resiliently mounted on an inner side of the frame structure bounding the chamber and is pre-loaded by at least one spring structure. The spring structure allows for a simple return of the movable valve parts.

Furthermore, in the microfluidic conveying system provided according to the present disclosure, the electrode structures are arranged opposite each other within the chamber and each have a first and a second electrode as well as a third and a fourth electrode.

Furthermore, in the microfluidic conveying system provided according to the present disclosure, the first and third electrodes are arranged on inner sides of the frame structure, facing the chamber.

Advantageously, the microfluidic conveying system is designed such that the second and fourth electrodes are arranged on the rear sides of the movable valve parts. This results in a particularly slim design of the microfluidic conveying system.

In the microfluidic conveying system according to the present disclosure, the electrode structures, comprising the first and second electrodes as well as the third and fourth electrodes, are provided with electrode fingers that engage with one another to form a comb drive.

In addition to the arrangement of flat electrodes, the electrodes can also have electrode fingers that are arranged opposite each other in a comb-like manner, so that various designs are available.

Furthermore, the present disclosure relates to a method for operating a microfluidic conveying system. According to an example embodiment, the method comprises at least the following method steps:
a) the valve structures 1 and 2 are set into vibration by energizing the electrode structures in such a way that,
c) at the electrodes situated opposite one another, the first and third electrodes are supplied with DC voltage, and the second and fourth electrodes are supplied with AC voltage, or
c) at the electrodes situated opposite one another, the first and third electrodes are supplied with AC voltage, and the second and fourth electrodes are supplied with DC voltage, and
d) the second electrodes are operated with a phase shift of 180° relative to the fourth electrodes, in such a way that
e) a movement in the same direction of the valve structures is generated.

The method provided according to the present disclosure allows the microfluidic conveying system of the present disclosure to continuously convey a flow of medium through the chamber, achieving high pumping efficiency.

Furthermore, the method provided according to the present disclosure is characterized in that, in a passive state, the first and second electrodes, situated opposite one another, of the electrode structure 1, and the third and fourth electrodes, situated opposite one another, of the electrode structure 2, are operated with a voltage of the same sign, increasing a distance between these electrodes as a result.

In the method proposed according to the present disclosure, it is further provided that, in the passive state, the first opening is closed by the valve structure 1, while at the same time, by operating the third and fourth electrodes with voltages of opposite sign, the valve structure 2 puts the second opening of the chamber into an open state and a flow of medium occurs.

The method according to the present disclosure makes it possible to alternately open and close the first and the second opening in such a way that a flow of medium into and out of the chamber is created. The flow of medium is created by the coupling of, for example, an ultrasonic vibration through the at least one ultrasound-generating element which is in the form of a membrane and assigned to the chamber. This at least one ultrasonic vibration is modulated by the valve structures 1 and 2.

Furthermore, in the method provided according to the present disclosure, it can be provided that the electrode structures are operated in the resonance range. Operating the electrode structures in the resonance range enables an extremely energy-efficient drive. The corresponding resonance can be adjusted by the mass or stiffness of the component. In particular, the resonance frequency has to be adapted to the ultrasound frequency to be modulated, so that a directed flow of medium is generated by opening the valve structures 1 and 2 at the correct time. The ultrasonic frequency can be freely selected. Depending on the desired application, for example in the case of a μ-speaker (acoustic application), an ultrasound frequency in the range of more than 20 kHz should be selected. However, in other applications this frequency or frequency band may lie in significantly different ranges.

Finally, the present disclosure relates to the use of the microfluidic conveying system and the method for operating a MEMS-based loudspeaker, in particular a micro-loudspeaker (μ-speaker). For example, a very effective valve structure can be represented by two valve structures that are either driven in planar manner by electrodes arranged in relation to each other or by means of a comb drive made of electrodes. The solution proposed according to the present disclosure makes it possible, for example in pump loudspeakers, to increase the pumping power and thus increase the overall efficiency of the component. In particular, the proposed microfluidic conveying system can be operated in the resonance range, achieving a very low energy requirement as a result.

The solution provided according to the present disclosure allows at least two first and second openings provided in a frame structure around a chamber in a horizontal or vertical orientation to be opened and closed alternately, so that a continuous flow of medium into and out of the chamber of the microfluidic conveying system can be achieved. Precise switching can therefore generate a directed pump current in one direction or the other.

By adding at least one ultrasound-generating component, for example in the form of a membrane, the solution proposed according to the present disclosure can also be used for ultrasonic modulation of the flow of medium. The at least one ultrasound-generating component can for example be integrated into the frame structure, the ceiling region, or the floor region of the substrate of the microfluidic system. The microfluidic system proposed according to the present disclosure is characterized by very high efficiency, since both the at least one ultrasound-generating component and the valve structures can be operated in the resonance range. Furthermore, the valve structures shown are characterized by a very high degree of locking, which allows for a very high pumping efficiency.

The solution provided according to the present disclosure provides a microfluidic conveying system, the sound pressure level (SPL) of which is significantly improved.

The solution proposed according to the present disclosure allows for active controlling through a precisely chosen phase shift between the valves and the drive structure, i.e. the electrode structure, so that the strength of pump strokes of the flow of medium can be freely selected depending on the application. Furthermore, the pumping direction of the flow of medium can advantageously be inverted. A phase shift can be implemented between the valve structures and the electrode structures, so that a component can be used for pumping and drawing. The drive structure in the form of the electrode structure covers the valve structures including comb structures, resulting in a reduced chip surface requirement and thus a surface-optimized design.

### BRIEF DESCRIPTION OF THE DRAWINGS

Example embodiments of the present disclosure are explained in greater detail with reference to the figures and the following description.

FIGS. 1A and 1B show a first embodiment variant of the microfluidic conveying system provided according to the present disclosure.

FIGS. 2A and 2B show an embodiment variant of the microfluidic conveying system provided according to the present disclosure with comb-like electrode structures, in top and side view.

FIGS. 3A, 3B show a further embodiment variant of the microfluidic conveying system proposed according to the present disclosure with comb-like electrode structures and movable and stationary valve parts formed in a comb structure, in top and side view.

FIGS. 4A-4D show a further embodiment variant of the microfluidic conveying system proposed according to the present disclosure in top and side view with a first and second opening formed in the floor region and/or the ceiling region.

FIGS. 5A, 5B show a further embodiment variant of the microfluidic conveying system proposed according to the present disclosure, in which the movable valve parts are connected to each other by a connecting structure.

### DETAILED DESCRIPTION OF EXAMPLE EMBODIMENTS

In the following description of the embodiments of the present disclosure, identical or similar elements are denoted by the same reference signs, and a repeated description of these elements in individual cases is dispensed with. The figures show the subject-matter of the present disclosure only schematically.

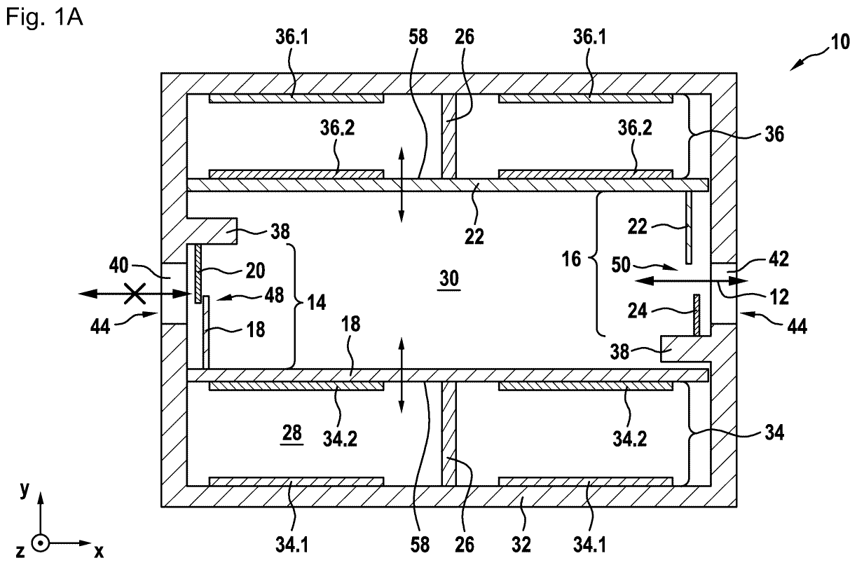

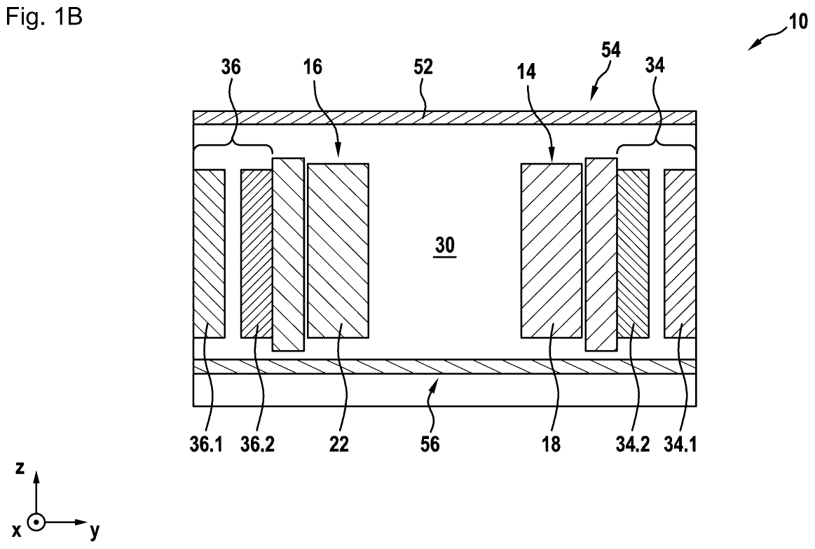

FIGS. 1A and 1B show a first embodiment variant of the microfluidic conveying system 10 proposed according to the present disclosure in top view and side view.

A microfluidic conveying system 10 conveys a flow of medium 12 in the manner of a pump. In the flow of medium 12, a gaseous or liquid medium is moved through a chamber 30 of the microfluidic conveying system 10 as part of an exchange of medium. For this purpose, a valve structure 1 14 and a valve structure 2 16 are provided. The valve structure 1 14 comprises a movable valve part 18 and a stationary valve part 20. The valve structure 2 16 comprises a movable valve part 22 and a stationary valve part 24. In the top view according to FIG. 1A, these are each assigned to a first opening 40 or a second opening 42. By the valve structures 1 and 2 14, 16 the first and second openings 40, 42 of the microfluidic conveying system 10 can be alternately opened and closed, so that the flow of medium 12 into and out of the chamber 30 of the microfluidic conveying system 10 results. The valve structures 1 and 2 14, 16 are resiliently mounted on the sides of the frame structure 32 which surrounds the chamber 30. At least one spring structure 26 acts as a resilient mounting. A plurality of spring structures 26, not shown in the drawing, may also be provided for the bearing and pre-loading of the movable valve parts 18, 22 of the valve structures 1 and 2 14, 16.

The movable valve parts 18, 22 of the valve structures 1 and 2 14, 16 are completed by valve parts 20, 24 formed in a stationary or fixed manner on the frame structure 32 or on projections 38 thereof.

As can also be seen from the top view according to FIG. 1A, the valve structures 1 and 2 14, 16 are moved by electrode structures, namely an electrode structure 1 34 and another electrode structure 2 36. The valve structures 1 and 2 14, 16 are excited to vibration via the electrode structures 1 and 2 34, 36. The electrode structures 1 and 2 34, 36, as shown in top view according to FIG. 1A, each comprise electrodes situated opposite one another, namely the electrode structure 1 34 comprises a first electrode 34.1, which is planar in FIG. 1A, and a second electrode 34.2 situated opposite thereto, which is also planar. Analogously, the electrode structure 2 36 comprises a third planar electrode 36.1 and a fourth planar electrode 36.2. The planar second electrodes 34.2 and the likewise planar electrodes 36.2 are each arranged on the rear sides 58 of the movable valve parts 18, 22.

According to the top view in FIG. 1A, the first and second openings 40, 42 extend perpendicularly to the plane of the drawing and accordingly have a vertical orientation 44. While in the top view according to FIG. 1A, the first opening 40 through the valve structure 1 14 is in a closed state 48, the second opening 42 through the valve structure 2 16, arranged opposite thereto, is in an open state 50.

The first to fourth electrodes 34.1, 34.2, 36.1, 36.2, which are each planar and are situated opposite each other in FIG. 1A, can either be supplied with AC voltage and the correspondingly complementary electrodes 34.1, 34.2, 36.1, 36.2 with DC voltage. In the exemplary embodiment shown in FIG. 1A, the first electrode 34.1 and the third electrode 36.1 are supplied with DC voltage, whereas the second electrode 34.2 and the fourth electrode 36.2 are supplied with AC voltage. The second electrodes 34.2 are operated with a phase shift of 180° relative to the fourth electrodes 36.2, bringing about a movement in the same direction of the two valve structures 1 and 2 14, 16.

The choice of which of the mutually complementary electrodes 1 to 4 34.1, 34.2, 36.1, 36.2 is operated with AC voltage or with DC voltage is interchangeable. It is of course possible that the second electrodes 34.2 and fourth electrodes 36.2 are supplied with DC voltage and the first electrodes 34.1 and the third electrodes 36.1 with AC voltage.

In the example shown in FIG. 1A, each valve structure 1 and 2 14, 16 shows two electrodes supplied with AC voltage, namely the second electrode 34.2 and the fourth electrode 36.2, as well as two electrodes supplied with DC voltage, namely the first electrode 34.1 and the third electrode 36.1. This should not be understood as limiting, as it is possible to use either just one electrode supplied with DC voltage or AC voltage, or a plurality of such electrodes.

The valve structures 1 and 2 14, 16 are supplemented by said stationary complementary structures, namely said stationary valve parts 20, 24. In their passive state, these prevent a flow of medium 12 between the interior of the chamber 30 and its surroundings through the first and the second opening 40, 42. The passive state mentioned here is characterized in that the mutually complementary electrodes of electrodes 1 to 4 34.1, 34.2, 36.1, 36.2 are supplied with a voltage of the same sign, so that no attractive effect is generated between them. The spring force applied by the spring structures 26 correspondingly pushes the movable valve parts 18, 22, for example, the valve structure 1 14, away from the frame structure 32. This increases the distance between the electrodes, for example between the first electrode 34.1 and the second electrode 34.2. In the illustrated example according to the representation in FIGS. 1A and 1B, the valve structure 1 14 is in the passive state, thus closing the first opening 40, while at the same time the valve structure 2 16 is in the active state, which means that the third electrode 36.1 and the fourth electrode 36.2 are operated with voltages of opposite signs. This creates an attractive force between them and moves the valve structure 2 16 toward the frame structure 32, opening the second opening 42 and establishing a flow of medium 12 or exchange of medium 12 through the chamber 30 as a result. The structure shown schematically in the top view according to FIG. 1A allows the first and second openings 40, 42 to be opened and closed alternately, thus enabling a flow of medium 12 into and out of the chamber 30. By correctly switching, a directed pump current can thus be generated in one direction or the other. If an ultrasound-generating component in the form of a membrane 52 is added to the chamber 30, as indicated in FIG. 1B, the microfluidic conveying system 10 proposed according to the present disclosure can be used for ultrasonic modulation. The illustration in FIG. 1B shows that in the embodiment variant shown there, the at least one ultrasound-generating component 52 is located, for example, in the ceiling region 54 above the chamber 30. Alternatively, it is possible to arrange at least one ultrasound-generating component 52 in the form of a membrane in the floor region 56 on the underside of the chamber 30 of the microfluidic conveying system 10. A plurality of ultrasound-generating components 52 can also be arranged in the floor region 56, in the side walls of the chamber 30, and/or in the ceiling region 54. By correctly switching the electrode structures 1 and 2 34, 36, the ultrasonic wave coupled in by the at least one ultrasound-generating component 52 can be modulated to represent a pump loudspeaker. This is characterized by very high efficiency, since both the ultrasound-generating component 52 and the two valve structures 1 and 2 14, 16 can be operated in the resonance range. Furthermore, the valve structures 1 and 2 14, 16 shown schematically in FIG. 1A are characterized by a high degree of locking, which enables a very high pumping efficiency to be achieved.

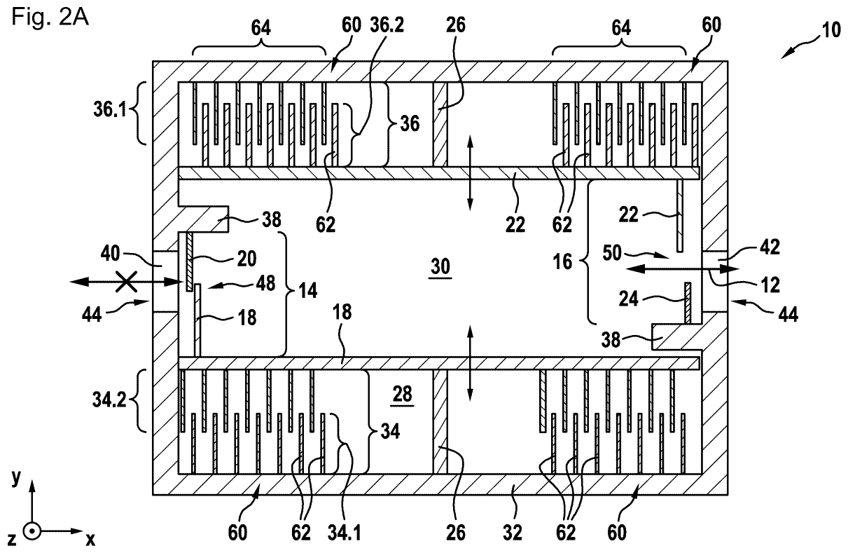

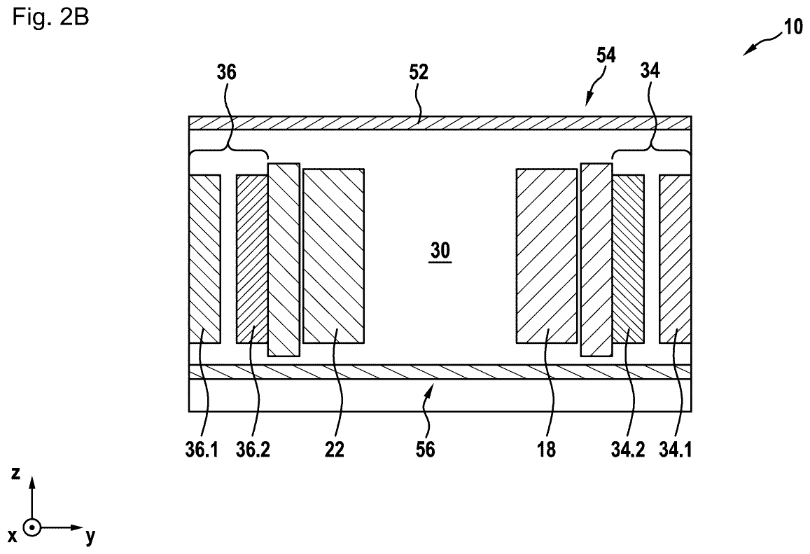

The illustrations in FIGS. 2A and 2B show a first alternative embodiment variant of the microfluidic conveying system 10 proposed according to the present disclosure, in which the electrodes 1 to 4 34.1, 34.2, 36.1, 36.2, which drive the valve structures 1 and 2 14, 16, are designed as a comb drive 60. In the second variant embodiment of the microfluidic conveying system 10 proposed according to the present disclosure, said electrodes 1 to 4, 34.1, 34.2, 36.1, 36.2 are not planar, but have electrode fingers 62 which extend in the chamber 30 perpendicular to the relevant movable valve parts 18, 22. Higher forces can be generated by the comb drive 60 shown in FIGS. 2A and 2B in order to move the valve structures 1 and 2 14, 16. The individual electrode fingers 62 of the first to fourth electrodes 34.1, 34.2, 36.1, 36.2 exhibit a multiple overlap 64, as indicated in the top view according to FIG. 2A. Furthermore, the second embodiment variant according to FIGS. 2A and 2B corresponds to the first embodiment variant of the microfluidic conveying system 10 proposed according to the present disclosure shown in FIGS. 1A and 1B.

The electrode structures 1 and 2 34, 36, which are provided for moving the movable valve parts 18, 22 of the valve structures 1 and 2 14, 16, can be operated according to the following method:
a) the valve structures 1 and 2 14, 16 are set into vibration by energizing the electrode structures 34, 36 in such a way that,
b) of the electrodes situated opposite one another 34.1, 34.2, 36.1, 36.2, the first and third electrodes 34.1, 36.1 are supplied with DC voltage and the second and fourth electrodes 34.2, 36.2 are supplied with AC voltage, or
c) at the electrodes situated opposite one another 34.1, 34.2, 36.1, 36.2, the first and third electrodes 34.1, 36.1 are operated with AC voltage and the second and fourth electrodes 34.2, 36.2 with DC voltage, and
d) the second electrodes 34.2 are operated with a phase shift of 180° relative to the fourth electrodes 36.2, in such a way that
e) a movement in the same direction of the valve structures 1 and 2 14, 16 is generated.

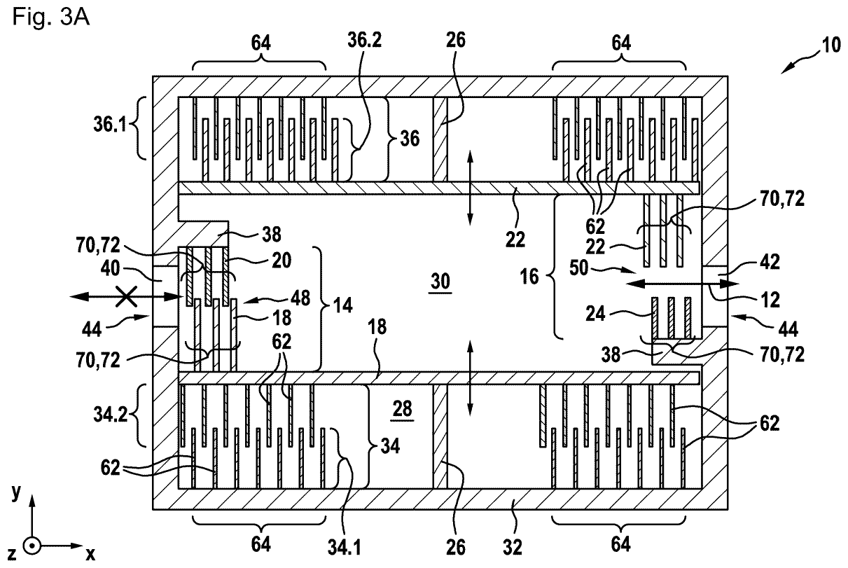

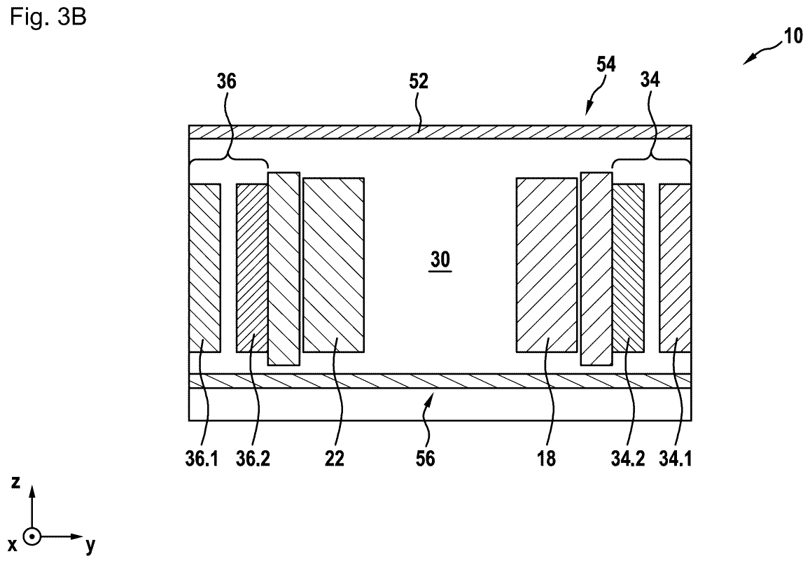

FIGS. 3A and 3B show a third embodiment variant of the microfluidic conveying system 10, which, in contrast to the first and second embodiment variants of the microfluidic conveying system 10 proposed according to the present disclosure and described above, is characterized in that the valve structures 1 and 2 14, 16 are themselves designed as a comb structure 70. This applies to both the movable valve parts 18, 22 of the valve structures 1 and 2 14, 16 and the stationary valve parts 20, 24 of the valve structures 1 and 2 14, 16 which are fixedly arranged on the frame structure 32. The aforementioned valve structures 1 and 2 14, 16 or their movable valve parts 18, 22 or their stationary valve parts 22, 24 can engage with one another in the active state of the valve structures 1 and 2 14, 16, which can further increase the locking effectiveness of the valve structures 1 and 14, 16. The number of teeth or the cascade-like arrangement 72 of the individual lamella parts 74, which can be used to form the comb structures 70 according to the representations in FIGS. 3A and 3B, is variable and can be adapted as needed. With regard to the first and second openings 40, 42, these are located at the ends of the chamber 30 in a vertical orientation 44, analogous to the embodiment variants of the microfluidic conveying system 10 proposed according to the present disclosure, and described above.

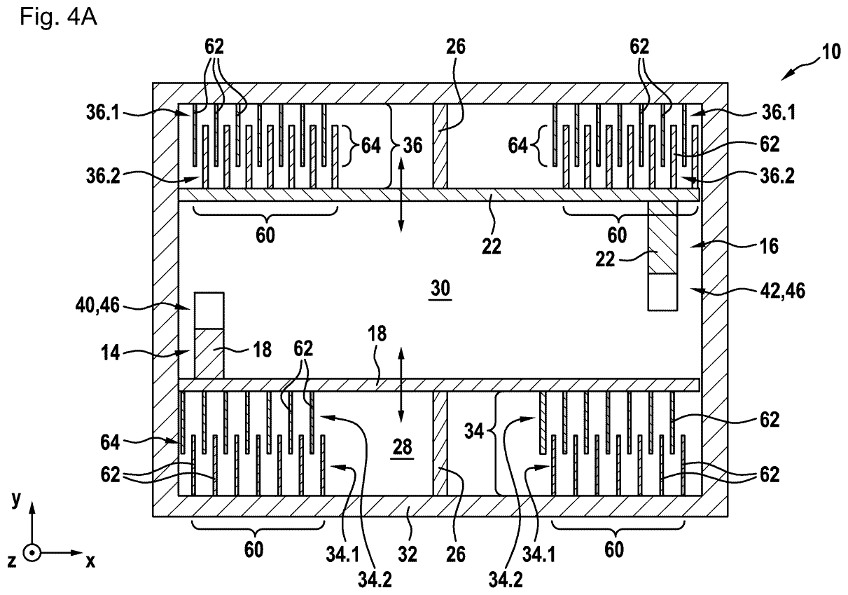

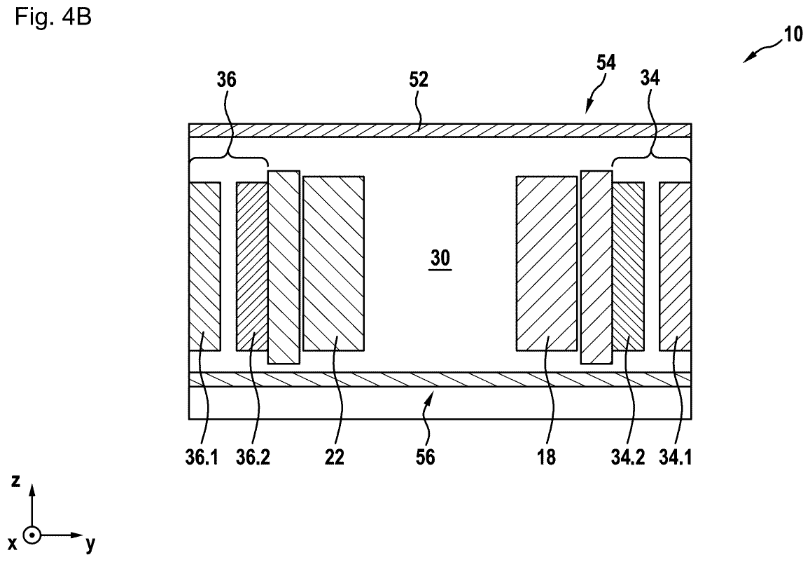

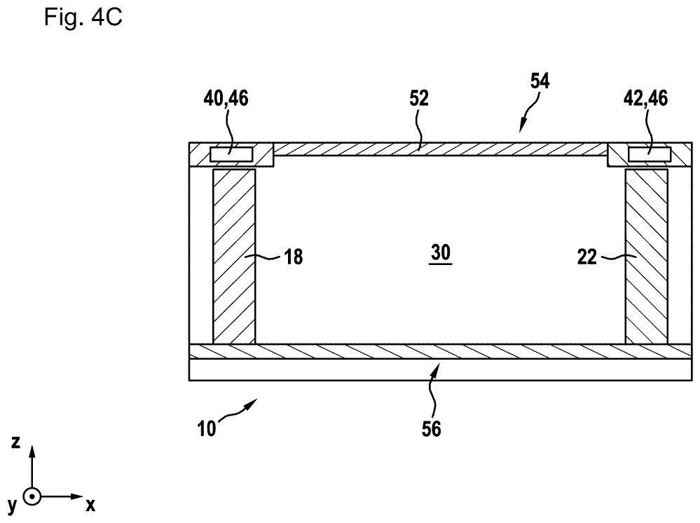

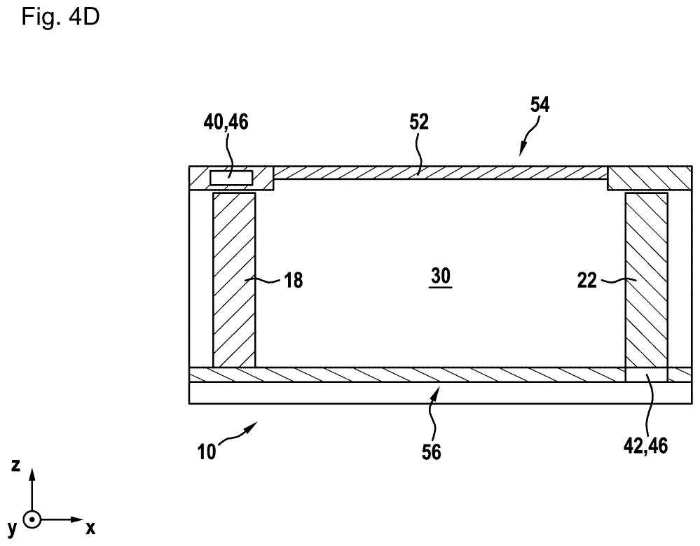

FIGS. 4A and 4B show a fourth embodiment variant of the microfluidic conveying system 10 proposed according to the present disclosure. In this embodiment variant, the first and second openings 40, 42 are not open in the X direction, but are located in the plane in which the ultrasound-generating component 52, preferably designed as a membrane, can be arranged. The first and second openings 40, 42 according to the fourth embodiment variant of the microfluidic conveying system 10 proposed according to the present disclosure are openings in the Z direction. By moving the valve structures 1 and 2 14, 16 in the +/−Y direction, the first and second openings 40, 42 are opened or closed. FIG. 4A shows a top view of the fourth embodiment variant. FIG. 4B shows a cross section along the Y/Z plane, and FIG. 4C shows a cross section along an X/Z plane.

In the fourth embodiment variant of the microfluidic conveying system 10 shown in FIGS. 4A to 4D and proposed according to the present disclosure, the valve structures 1 and 2 14, 16 have the same height along the Z-direction as the electrode structures 1 and 2 34, 36 or their electrodes 1 to 4 34.1, 34.2, 36.1, 36.2. In other embodiment variants not shown in detail here, it is possible that the valve structures 1 and 2 14, 16 can also be made lower or higher. The width of the valve structures 1 and 2 14, 16 along the X-direction corresponds at least to an opening width of the first and second openings 40, 42, but is preferably larger than the opening width in order to ensure a high locking efficiency.

The positioning of the first and second openings 40, 42 can vary and can either be arranged in the ceiling region 54 or in the floor region 56 (not shown in detail here), as shown in FIGS. 4A to 4D, or it is possible to arrange one of the first and the second openings 40, 42 in the ceiling region 54, as shown in FIG. 4D, and one in the floor region 56.

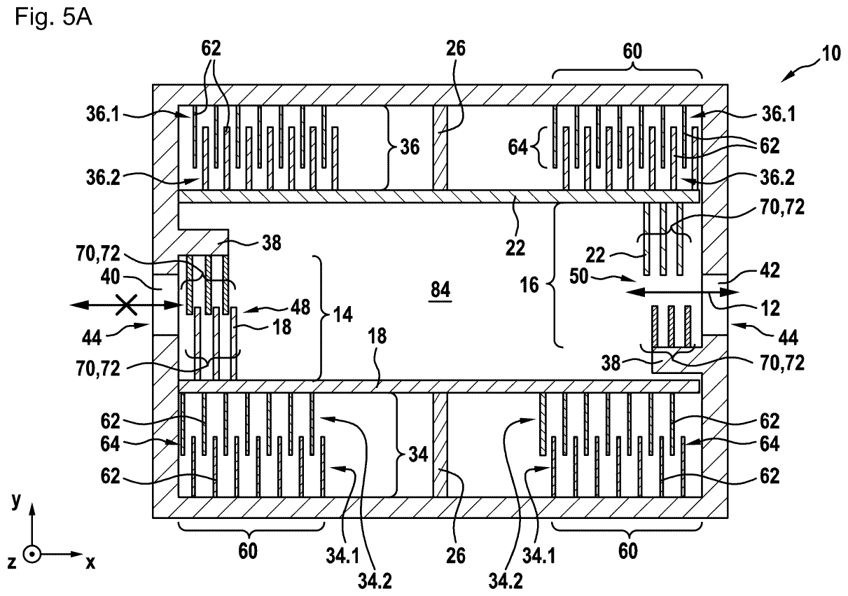

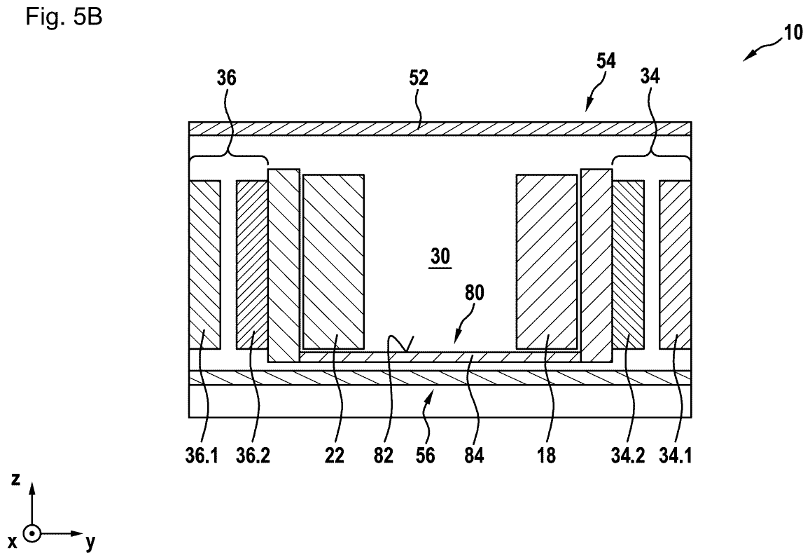

FIGS. 5A and 5B show a fifth embodiment variant of the microfluidic conveying system 10 proposed according to the present disclosure. In this embodiment variant, the valve structures 1 and 2 14, 16 are mechanically coupled to each other by a connecting structure 80 that is substantially planar. This couples the movement of the moving parts of the valve structures 1 and 2 14, 16, namely the moving valve parts 18, 22, to one another, ensuring a symmetrical movement of the two valve structures 1 and 2, 14, 16 as a result.

The connecting structure 80 can be designed as a surface 42, representing a base plate 84, which can effectively prevent acoustic leakage paths in particular. Due to the mechanical coupling by means of the connecting structure 80, the spring structures 26, as shown above, do not have to act as return elements. This allows for defined controlling of the valve structures 1 and 2, 14, 16, since the return force is generated in each case by the pair of electrodes 1 to 4 34.1, 34.2, 36.1, 36.2 arranged opposite one another. This results in greater robustness, especially against impacts and vibrations.

In all of the five illustrated embodiment variants of the microfluidic conveying system 10 proposed according to the present disclosure, a plurality of valve structures 1 and 2 14, 16 can be used which can each be operated in phase or phase-shifted relative to each other. In particular, a phase-shifted operation of the valve structures 1 and 2 14, 16 can, for example, cause a temporal gradient in the opening and thus in the flow of medium 12.

The microfluidic conveying system 10 proposed according to the present disclosure, in its forms shown above, can be used for example in MEMS, such as pump microphones in microfluidics, and for MEMS-based micro-loudspeakers (μ-speakers).

The present disclosure is not limited to the exemplary embodiments described here and the aspects emphasized therein. Rather, a plurality of modifications are possible within the range indicated by the present disclosure and are within the scope of the activities of a person skilled in the art, in view of the disclosure herein.

What is claimed is:

1. A microfluidic conveying system, comprising:
a substrate;
a chamber formed in the substrate;
a ceiling region and a floor region that bound the chamber;
first and second openings that allow a flow of medium through the chamber; and
at least one component assigned to the chamber and configured to generate a pressure difference, the pressure difference is modulated by valve structures to form a directed flow of medium.

2. The microfluidic conveying system according to claim 1, wherein the at least one component configured to generate the pressure difference is a planar or comb-like electrode structure, and the valve structures each include at least one movable valve part.

3. The microfluidic conveying system according to claim 2, wherein, each of the movable valve parts interacts with at least one corresponding stationary valve part received in the chamber.

4. The microfluidic conveying system according to claim 3, wherein the at least one stationary valve part in the chamber is formed on projections of a frame structure surrounding the chamber.

5. The microfluidic conveying system according to claim 1, wherein: (i) each of the valve structures has a movable valve part and a stationary valve part, or (ii) each of the valve structures has individual lamella parts arranged in a comb structure, which can be positioned in or out of overlap with each other for opening or closing the first and second openings.

6. The microfluidic conveying system according to claim 4, wherein the at least one movable valve part is resiliently mounted on an inner side of the frame structure surrounding the chamber and is pre-loaded by at least one spring structure.

7. The microfluidic conveying system according to claim 1, wherein the at least one component configured to generate the pressure difference includes planar or comb-like electrode structures, and the valve structures each include at least one movable valve part, wherein the electrode structures are arranged opposite each other within the chamber, a first one of the electrode structures includes first and second electrodes, and a second one of the electrode structures includes third and fourth electrodes.

8. The microfluidic conveying system according to claim 7, wherein the first and third electrodes are arranged on inner sides of the frame structure facing the chamber.

9. The microfluidic conveying system according to claim 7, wherein the second and fourth electrodes are arranged on rear sides of the movable valve parts.

10. The microfluidic conveying system according to claim 1, wherein the at least one component configured to generate the pressure difference includes planar or comb-like electrode structures, wherein the electrode structures include first and second electrodes including first electrode fingers which engage with one another to form a first comb drive, and third and fourth electrodes including second electrode fingers which engage with one another to form a second comb drive.

11. A method for operating a microfluidic conveying system, the microfluidic conveying system including:
a substrate,
a chamber formed in the substrate,
a ceiling region and a floor region that bound the chamber,
first and second openings that allow a flow of medium through the chamber, and
at least one component assigned to the chamber and configured to generate a pressure difference, the pressure difference is modulated by valve structures to form a directed flow of medium,
wherein the at least one component configured to generate the pressure difference includes planar or comb-like electrode structures, and the valve structures each include at least one movable valve part, wherein the electrode structures are arranged opposite each other within the chamber, a first one of the electrode structures includes first and second electrodes arranged opposite to one another, and a second one of the electrode structures includes third and fourth electrodes arranged opposite to one another,
the method comprising the following steps:
setting the valve structures into vibration by energizing the electrode structures in such a way that: (i) the first and third electrodes are supplied with DC voltage and the second and fourth electrodes are supplied with AC voltage, or (ii) the first and third electrodes are operated with AC voltage and the second and fourth electrodes are operated with DC voltage, wherein the second electrodes are operated with a phase shift of 180° relative to the fourth electrodes, in such a way that a movement of the valve structures in the same direction is generated.

12. The method according to claim 11, wherein, in a passive state, the first and second electrodes of the first one of the electrode structures are operated with a voltage of the same sign to increase a distance between the first and second electrodes, and the third and fourth electrodes of the second one of the electrode structures are operated with a voltage of the same sign to increase a distance between the third and fourth electrodes.

13. The method according to claim 11, wherein, in a passive state, the first opening is closed by a first one of the valve structures, while at the same time, by operating the third and fourth electrodes with voltages of opposite sign, a second one of the valve structures puts the second opening into an open state, as a result of which a flow of medium occurs.

14. The method according to claim 11, wherein the first and second openings are alternately opened and closed in such a way that a flow of medium into and out of the chamber occurs.

15. The method according to claim 11, wherein the electrode structures are operated in a resonance range.

16. The method according to claim 11, wherein an ultrasonic modulation of the flow of medium is carried out using an ultrasound-generating component including at least one membrane, arranged in a ceiling region and/or in a floor region, and is carried out with frequencies of more than 20 kHz.

17. The microfluidic conveying system according to claim 1 wherein the microfluidic conveying system is used for operating a MEMS-based loudspeaker.
